(19) United States
(12) Patent Application Publication
(10) Pub. No.: US 2015/0355458 A1
(43) Pub. Date: Dec. 10, 2015

(54) MICRO-MACHINED OPTICAL MIRROR SWITCH

(71) Applicants: Shuyun (Steve) Wu, Acton, MA (US); Jing Zhao, Winchester, MA (US)

(72) Inventors: Shuyun (Steve) Wu, Acton, MA (US); Jing Zhao, Winchester, MA (US)

(21) Appl. No.: 14/300,392

(22) Filed: Jun. 10, 2014

(51) Int. Cl. G02B 26/08; B81C 1/00

(52) U.S. Cl. CPC G02B 26/0833; B81C 1/00523

(57) ABSTRACT

The present disclosure provides a micro-machined switchable optical mirror device with a fast response speed. The mirror device includes a substrate defining a gap space, and a mirror assembly disposed on the substrate and deflectable in the gap space, the mirror assembly including a free end cantilever and a reflector on the cantilever, wherein the cantilever is anchored on the substrate adjacent a side of the gap space through an elastic member. In one aspect, the mirror device further includes a stop spring at an end of the cantilever opposing the elastic member.

### STATEMENT REGARDING FEDERALLY SPONSORED RESEARCH OR DEVELOPMENT

This invention was made with government support under Contract Number W909MY-12-C-0018 awarded by the US Army Contracting Command, Subcontract Number SA-04, awarded by Banc 3, Inc. under Prime Contract No. W909MY-12-D-0005-0002 awarded to Banc 3, Inc. by the US Army and Subcontract Number SA-05, awarded by Banc 3, Inc. under Prime Contract No. W909MY-12-D-0005-0002 awarded to Banc 3, Inc. by the US Army. The government has certain rights in the invention.

### BACKGROUND

The present disclosure relates to a micro-machined optical mirror switch and a method for fabricating the same. More particularly, the present disclosure relates to a silicon-based, micro-machined optical mirror switch with a fast response speed and a method for fabricating the same.

Micro-Electro-Mechanical Systems (MEMS) is a fast growing manufacturing technology that produces ultra-fine mechanical devices at a very low cost. MEMS benefits from the economics of scale by employing the batch fabrication established in the semiconductor industry. Moreover, MEMS can be constructed using single-crystal silicon, which is an ideal material for mechanical devices, partly because single-crystal silicon has virtually no hysteresis and hence almost no energy dissipation. Further, single-crystal silicon is less prone to fatigue damages, and thus allows for a prolonged service lifetime. For example, single-crystal silicon may sustain over trillions of mechanical flexing cycles without breaking.

MEMS based moving mirrors have been widely used in communication components such as switches and attenuators and extensively use in digital light projectors (DLPs) and laser scanners. However, conventional MEMS mirror switches are limited in switching speed. There is an acute need to have fast MEMS optical mirrors for fast optical switches supporting the insatiable growth of internet bandwidth and other applications such as micro-scanners, laser Q-switching, optical shutters, etc. Fast optical MEMS mirror finds extensive applications in telecommunications, astrophysics, biology, medical imaging, etc.

### SUMMARY

In light of the above, the present disclosure provides a MEMS optical mirror switch that is optimized to achieve a significantly increased electrical response speed. For example, the fast electrical response speed may be achieved by operating the MEMS optical mirror switch in a near breakdown field region.

In one aspect, the mirror switch of the present disclosure includes a substrate defining a gap space, and a mirror assembly disposed on the substrate and deflectable in the gap space, the mirror assembly including a free end cantilever and a reflector on the cantilever, wherein the cantilever is anchored on the substrate adjacent a side of the gap space through an elastic member. The mirror device may further include a stop spring at an end of the cantilever opposing the elastic member. The mirror switch may further include an insulating layer disposed between the substrate and the mirror assembly. The mirror switch may further include a first electrode electrically coupled to the substrate, and a second electrode electrically coupled to the mirror assembly. The mirror switch may further include a highly reflective coating layer on the reflector. The mirror switch may further include a stop spring at an end of the cantilever opposing the elastic member. The mirror assembly of the mirror switch may further include an obstacle disposed adjacent a side of the gap space proximate the stop spring. The substrate of the mirror switch may include a plurality of apertures, the apertures opening the gap space to an exterior of the switchable optical mirror device.

The mirror assembly is switchable between a neutral state and a deflected state in response to an electrical voltage applied to the mirror assembly. In one embodiment, the cantilever may be substantially parallel to the substrate when the mirror assembly is at the neutral state. In an altemative embodiment, the cantilever may be substantially parallel to the substrate when the mirror assembly at the deflected state.

A number of other embodiments and fabrication of the mirror switch of the present disclosure are also disclosed herein below.

### BRIEF DESCRIPTION OF THE DRAWINGS

The present disclosure is to be read in conjunction with the accompanying drawings, in which:

FIG. 1 illustrates a sectional view of a mirror switch at an OFF state, in accordance with one embodiment of the present disclosure;

FIG. 2 illustrates a sectional view of a mirror switch at an ON state, in accordance with one embodiment of the present disclosure;

FIG. 3 illustrates a sectional view of a mirror switch in accordance with another embodiment of the present disclosure;

FIGS. 4A through 4D illustrate a process for fabricating an optical member of a mirror switch in accordance with one embodiment of the present disclosure;

FIGS. 5A through 5D illustrate a process for fabricating a support member of a mirror switch in accordance with one embodiment of the present disclosure; and

FIG. 6 illustrates a process for fabricating a mirror switch including the optical member and the support member, in accordance with one embodiment of the present disclosure.

### DETAILED DESCRIPTION

The following detailed description is of the best currently contemplated modes of carrying out the present disclosure. The description is not to be taken in a limiting sense, but is made merely for the purpose of illustrating the general principles of the present disclosure, because the scope of the present disclosure is defined by the appended claims.

As used herein, the singular forms “a,” “an,” and “the” include the plural reference unless the context clearly dictates otherwise.

Except where otherwise indicated, all numbers expressing quantities of ingredients, reaction conditions, and so forth used in the specification and the claims are to be understood as being modified in all instances by the term “about.” Further, any quantity modified by the term “about” or the like should be understood as encompassing a range of ±10% of that quantity.

For the purposes of describing and defining the present disclosure, it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

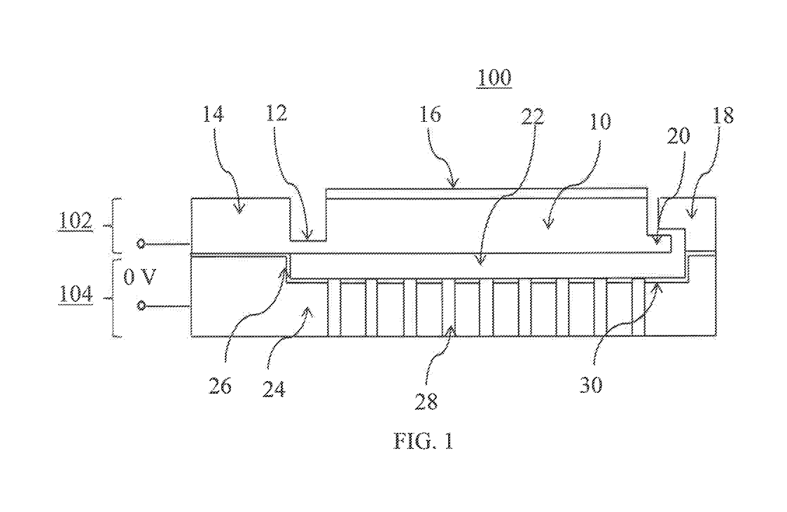

FIG. 1 illustrates a sectional view of an optical mirror switch 100 at an OFF state, in accordance with one embodiment of the present disclosure. Switch 100 may be manufactured from silicon wafers using the MEMS technology. In one embodiment, switch 100 includes a suspended optical member 102 and a support member 104 on which optical member 102 is securely disposed. In one embodiment, optical mirror switch 100 is at an OFF state because no electrical voltage is applied thereon.

Referring to FIG. 1, a suspended optical member 102 comprises support frame 14, a mirror electrode 10, a silicon cantilever spring 12, silicon spring stopper 20, and an upper stopper 18. In one embodiment, a suspended optical member 102 may be formed from a single crystal silicon wafer by etching silicon. It is appreciated that a silicon cantilever spring 12 is mechanically coupled and suspend a mirror electrode 10 over bottom electrode 104. In one embodiment, a spring stopper reduces the mechanical impact when the side of a suspended optical member 102 away from a cantilever spring 12 touches either bottom electrode or upper stopper during switching operation. In addition, suspended optical member 102 may optionally comprises a highly reflective layer 16 coated on mirror electrode element 10. In one embodiment, suspended optical member 102 is a free end cantilever, that is, one end of suspended optical member 102 is supported by silicon cantilever spring 12 which is anchored to support frame 14, while the other end of suspended optical member 102 is connected to spring stopper 20 which is free to fluctuate.

Referring again to FIG. 1, support member 104 comprises a bottom electrode body 24, a dielectric layer 30 on bottom electrode body 24, and a spacer step 26. Support member 104 may comprise a gap 22 formed by etching into bottom electrode body 24 to have a size commensurate with the size of a mirror electrode 10, so as to provide sufficient space for a mirror electrode 10 to move or fluctuate therein. Further, support member 104 may comprise a plurality of apertures 28 formed by etching through bottom electrode body 24 so as to allow air to escape from gap 22 while a mirror electrode 10 moves in gap 22. As shown in FIG. 1, optical member 102 and support member 104 securely are engaged with each other by aligning mirror electrode 10 and silicon spring stopper 20 of optical member 102 with gap 22 of support member 104. In various embodiments, bottom electrode body 24 is electrically grounded.

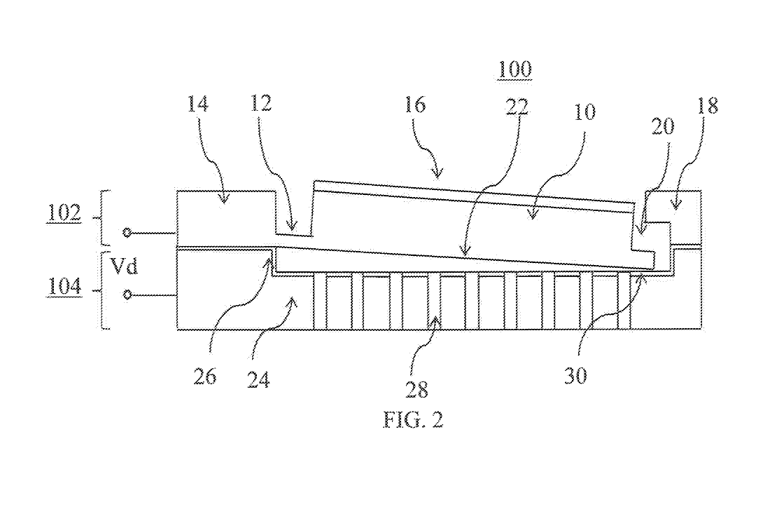

FIG. 2 illustrates a sectional view of a mirror switch 100 at an ON state, in accordance with one embodiment of the present disclosure. Mirror switch 100 in FIG. 2 is substantially the same as mirror switch 100 in FIG. 1, except that a voltage Vd is applied to mirror electrode 10 and bottom electrode 24 of mirror switch 100 in FIG. 2, while no voltage is applied to mirror switch 100 in FIG. 1. Voltage Vd applied to mirror switch 110 may induce electrostatic force that attracts mirror electrode 10 to move toward bottom electrode 24. As a result, MEMS mirror electrode 10 may be actuated and switched to an ON state in response to voltage Vd, as shown in FIG. 2. When mirror switch 100 is at an ON state, mirror electrode 10 is electrically insulated with bottom electrode 24 due to dielectric layer 30.

When voltage Vd is removed, mirror electrode 10 of switch 100 reverts back to the OFF state due to the restoration force of silicon spring 12, as shown in FIG. 1. When mirror electrode 10 reverts back to the OFF state, upper stopper 18 of optical member 102 may physically contact stop spring portion 20 of mirror electrode 10 so as to prevent mirror electrode 10 from over overshooting. Further, stop spring 20 may absorb the kinetic energy of the movable portion of optical member 102 and avoid hard contact when snapping down or restoring back to neutral position. As a result, both switching ring effect and mechanical damage are illuminated to enhance the stability and reliability of switch 100.

The mirror switch 100 of the present disclosure may be operated in an acceleration mode to achieve faster speed than conventional devices. While not desiring to be bound by theory, one physical explanation is that when the actuation force is much larger than the intrinsic MEMS mechanical spring force, the MEMS structure is at a non-steady state. The rotation rate is very fast, and the higher the applied voltage Vd, the faster the rotation rate. The recovery time and maximum actuation frequency is affected by the primary mechanical resonant frequency of mirror electrode suspension including silicon suspension spring 12, mirror electrode 10, and spring stopper 20. The mechanical resonant frequency depends mainly on the length and stiffness silicon spring 12. The mechanical resonant frequency f of suspended mirror structure (including reference numerals 10, 12, 16, and 20) may be related to the rotational spring constant K and rational inertia I of suspended mirror structure (including reference numerals 10, 12, 16, and 20 with the following formula:

$$f = \frac{1}{2 π} \sqrt{\frac{K}{I}} , \qquad ( Equation 1 )$$

The recovering time constant is

$$τ = \frac{1}{2 π f} = \sqrt{\frac{I}{K}} \qquad ( Equation 2 )$$

By MEMS technology, one may design rotational spring constant K and rational inertia I, such that the rotational frequency f can be as high as 16 kHz, which may correspond to a recovering time constant τ of about 10 μSec. In one instance, the mechanical resonant frequency ranges from about 1 kHz to about 100 kHz. By confining displacement of the mirror electrode 10 to a space between the upper stopper 18 and a surface of the 22, the optical mirror switch 100 is configured to withstand mechanical vibration from 10 to 2000 Hz and impact of to 2000 G.

In sum, when mirror switch 100 is at the OFF state, mirror 10 is in a neutral position suspended by spring portion 12, as illustrate in FIG. 1. When driving voltage Vd is applied, mirror switch 100 changes to the ON state by rotating mirror electrode suspension 10 to snap down to ground plate 24. The rotation is then stopped by stop spring portion 20, which lands on dielectric layer 30 on ground plate 24, as illustrate in FIG. 2. When a light beam impinges on mirror switch 100 at the OFF state, the light beam is reflected to a first destination. When mirror switch 100 is changed to the ON state, the light beam is then reflected to a second destination different from the first destination. Accordingly, mirror switch 100 of the present disclosure can be used to quickly control the optical path of a light beam.

As shown in FIGS. 1 and 2, mirror element 10 is suspended through silicon spring 12 over electrode plate 24 that is grounded. Gap 22 is formed between suspended mirror 10 and grounded electrode plate 24. Mirror 10 may be made of either N or P type heavily doped single crystal silicon with low resistivity for applying a driving voltage to achieve mirror switch by electrostatic force. By using silicon micro-machining technology, gap 22 may be precisely defined by spacer 26 and can be as small as in the micron range, in which a large electrostatic driving force may be produced to achieve fast switching, even with a low driving voltage. In one embodiment, gap 22 may has a thickness of less than 100 micro meters. In addition, the reflective loss is minimized due to the high quality mirror surface 10 as well as the high reflective coating 16 on mirror surface 10.

On electrode plate 24, arrays of through holes 28 are created to reduce air thin film squeeze damping and to increase switch speed. Stop spring portion 20 is created along the outer mirror edge away from suspended silicon spring 12 to avoid hard contact when mirror 10 switch down to ground plate 24. When mirror 10 restores back to the neutral position, stop spring portion 24 absorbs the kinetic energy by contacting upper stopper 18, thereby minimizing the ringing effect of switching.

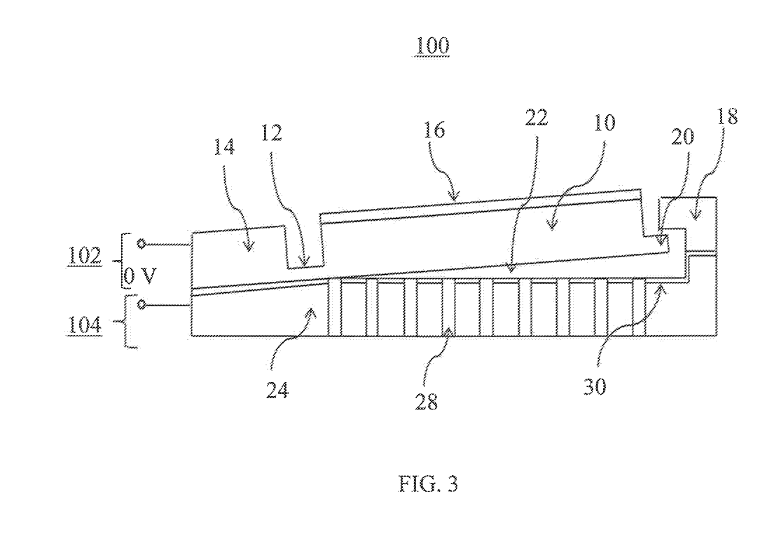

Although mirror 10 and ground plate 24 can be in parallel in order to reduce the complexity of assembly, as shown in FIGS. 1 and 2, mirror 10 and ground plate 24 can be arranged in a wedge form to further reduce driving voltage of the switch. FIG. 3 illustrates a sectional view of a mirror switch 100 in accordance with another embodiment of the present disclosure. Mirror switch 100 in FIG. 3 is substantially the same as mirror switch 100 in FIGS. 1 and 2, except that optical member 102 and support member 104 of mirror switch 100 in FIG. 3 are not parallel with each other. Rather, optical member 102 is deposed on support member 104 with a wedged angle. In one embodiment, the wedge form of mirror switch 100 may be achieved by selectively over-etching spacer 26 of support member 104 prior to engaging optical member 102 with support member 104.

Hereafter, a process for fabricating mirror switch 100 in accordance with on embodiment of the present disclosure is described.

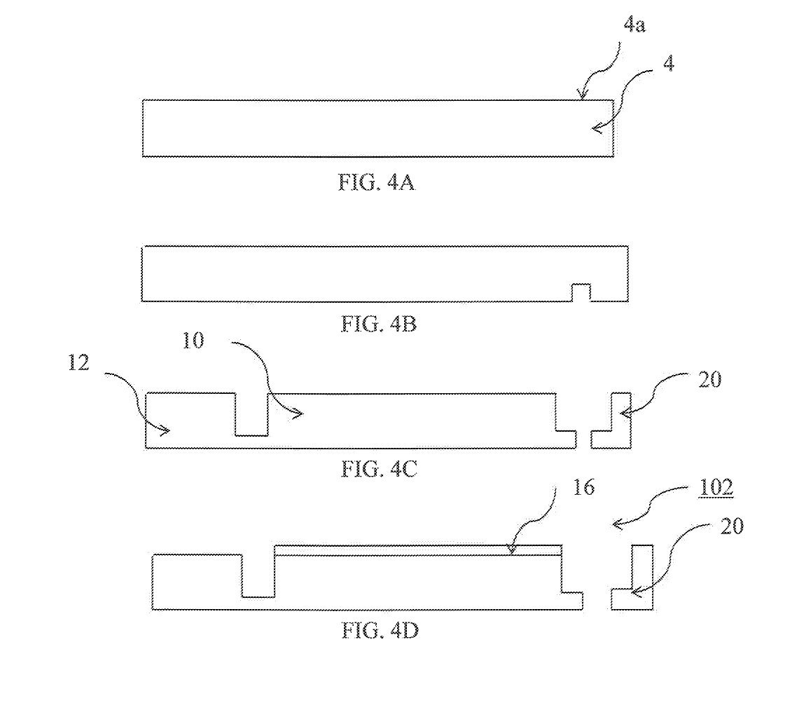

FIGS. 4A through 4D illustrate a process for fabricating optical member 102 of mirror switch 100 in accordance with one embodiment of the present disclosure. Referring to FIG. 4A, the fabrication process begins from silicon wafer In one embodiment, the top surface of silicon wafer may be the prime polished surface that is ideal for an optical mirror surface.

Referring to FIG. 4B, silicon is etched from one side to define the bottom boundaries of mirror electrode suspension including silicon suspension spring 12, mirror electrode 10, and spring stopper 20 It is noted that mirror electrode 10, and suspending spring 12 are mechanically and electrically coupled with each other.

Referring to FIG. 4C, silicon is etched from the other side, to define mirror element 10 and thickness of suspension spring 12 and spring stopper 20.

Referring to FIG. 4D, a high reflective (HR) layer 16, in which reflectivity is more than 99.5%, is coated on an upper surface of mirror element 10. In one embodiment, HR layer 16 may be formed by coating a HR material to an entire upper surface of optical element 102 and then etching the HR material such that only the portion on mirror element 10 remains. It is appreciated that, in other embodiments, HR layer 16 may be formed after the bonding of optical member 102 and support member 104. This completes the fabrication of optical element 102 of switch 100, as shown in FIGS. 1 and 2.

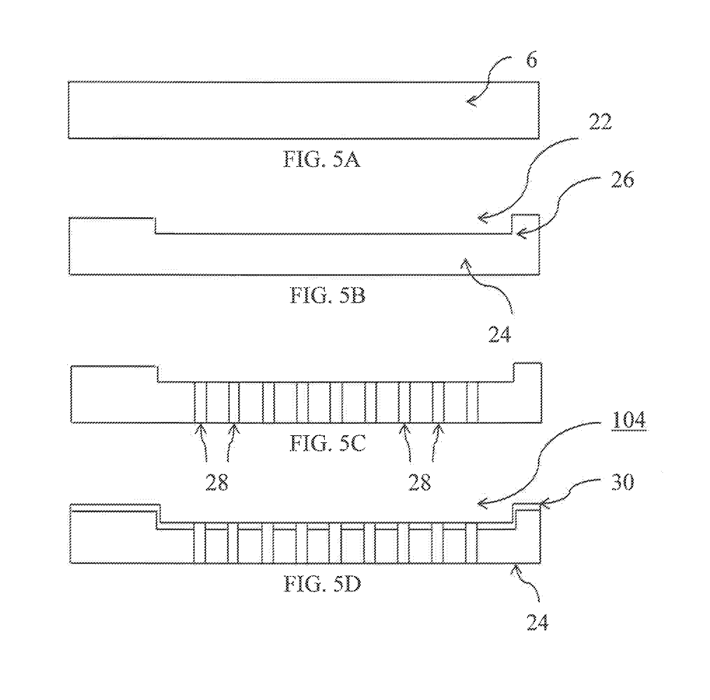

FIGS. 5A through 5C illustrate a process for fabricating support member 104 of mirror switch 100 in accordance with one embodiment of the present disclosure. Referring to FIG. 5A, the fabrication process begins from providing silicon wafer.

Referring to FIG. 5B, silicon is etched to form spacer 26 on electrode plate 24, thereby defining gap 22. In one embodiment, gap 22 may have a dimension commensurate to that of mirror electrode suspension including silicon suspension spring 12, mirror electrode 10, and spring stopper 20.

Referring to FIG. 5C, silicon is etched through to form an array of apertures 28. In one embodiment, apertures 28 are through holes that permit air to communicate between two sides of the silicon electrode 24.

Referring to FIG. 5C, a dielectric layer 30 is deposited on the top of bottom electrical plate 24. This completes the fabrication of support element 104 of switch 100, as shown in FIGS. 1 and 2.

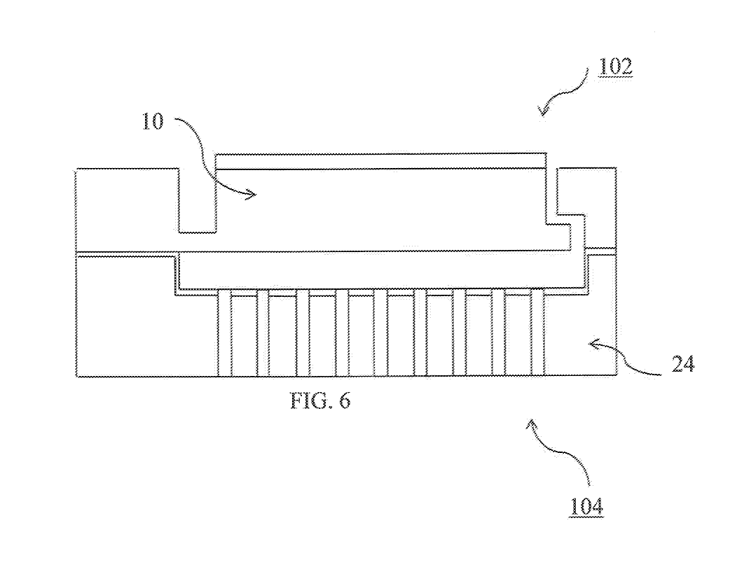

FIG. 6 illustrates a process for fabricating mirror switch 100 including optical member 102 and support member 104, in accordance with one embodiment of the present disclosure. Referring to FIG. 6, optical member 102 as shown in FIG. 4D and support member 104 as shown in FIG. 5D are bonded together by facing and aligning mirror electrode suspension including silicon suspension spring 12, mirror electrode 10, and spring stopper 20 with gap 22 of support member 104. Upper stopper is aligned between the edge of bottom electrode 24 and spring stopper 20, and bonded to the bottom electrode 24.

Referring to FIG. 6, once optical member 102 and support member 104 are bonded, mirror switches 100 fabricated on a large wafer may be separated into individual chip units. Each individual mirror switch 100 may then be wire bonded with electrical terminals such that a driving voltage may be applied to mirror electrode 10 and that bottom electrode 24 may be grounded. It is appreciated that, in alternative embodiments, a driving voltage may be applied to bottom electrode 24, while mirror electrode 10 may be grounded.

In view of the foregoing, it can be seen that the present disclosure provides a MEMS optical mirror switch that is optimized to achieve a significantly increased electrical response speed. It is to be understood that the method and the apparatus of the present disclosure are described for exemplary and illustrative purposes only. Various modifications and changes may be made to the disclosed embodiments by persons skilled in the art without departing from the scope of the present disclosure as defined in the appended claims.

What is claimed is:

1. A switchable optical mirror device, comprising:
a substrate defining a gap space; and
a mirror assembly disposed on the substrate and deflectable in the gap space, the mirror assembly comprising a free end cantilever and a reflector on the cantilever, wherein an end of the cantilever is anchored on the substrate adjacent a side of the gap space through an elastic member.

2. The switchable optical mirror device of claim 1, wherein the substrate comprises a plurality of apertures, the apertures opening the gap space to an exterior of the switchable optical mirror device.

3. The switchable optical mirror device of claim 1 further comprising a stop spring at an end of the cantilever opposing the elastic member.

4. The switchable optical mirror device of claim 3, wherein the mirror assembly further comprising an obstacle disposed adjacent a side of the gap space proximate the stop spring.

5. The switchable optical mirror device of claim 1, further comprising an insulating layer disposed between the substrate and the mirror assembly.

6. The switchable optical mirror device of claim 1, wherein the mirror assembly is switchable between a neutral state and a deflected state in response to an electrical voltage applied to the mirror assembly.

7. The switchable optical mirror device of claim 6, wherein the cantilever is substantially parallel to the substrate when the mirror assembly is at the neutral state.

8. The switchable optical mirror device of claim 6, wherein the cantilever is substantially parallel to the substrate when the mirror assembly is at the deflected state.

9. The switchable optical mirror device of claim 1, further comprising a first electrode electrically coupled to the substrate, and a second electrode electrically coupled to the mirror assembly.

10. The switchable optical mirror device of claim 1, further comprising a highly reflective coating layer on the reflector.

11. The switchable optical mirror device of claim 1, wherein the gap space is at most 100 microns.

12. The switchable optical mirror device of claim 1, wherein the mirror assembly is operable under an acceleration mode.

13. A method for manufacturing an optical switching device, the method comprising:
etching a first wafer to define a cantilever, an elastic member and a stop member;
coating a surface of the cantilever with a highly reflective layer; thereby forming an optical component;
etching a second wafer to define a gap;
etching the second wafer to define a plurality of apertures, the apertures operatively connecting a surface of the second wafer comprising the gap to a space adjacent an opposite surface of the second wafer; thereby forming a support component;
coating a surface of the second wafer on which they gap is defined with a dielectric layer; and
securely fastening the optical component and the support component by aligning the cantilever, the elastic member and the stop member defined on the first wafer with the gap defined on the second wafer.

14. The method of claim 13, further comprising:
forming a first electrode electrically coupled to the cantilever in the optical component; and
forming a second electrode electrically coupled to the second wafer.

15. The method of claim 13 wherein the first wafer and the second wafer comprise silicon.

16. The method of claim 13 wherein the first wafer comprises single crystal silicon.

17. A switchable optical mirror device, comprising:
a substrate defining a gap space;
a mirror assembly on the substrate and deflectable in the gap space, the mirror assembly comprising a cantilever and a reflector on the cantilever;
an elastic member adjacent a side of the gap space, the mirror assembly being anchored to the substrate through the elastic member;
a stop spring at an end of the cantilever opposing the elastic member; and an obstacle disposed adjacent a side of the gap space proximate the stop spring; wherein the substrate comprises a plurality of apertures, the apertures opening the gap space to an exterior of the switchable optical mirror device.

18. The switchable optical mirror device of claim 17, wherein the mirror assembly is switchable between a neutral state and a deflected state in response to an electrical voltage applied to the mirror assembly.

19. The switchable optical mirror device of claim 18, wherein the cantilever is substantially parallel to the substrate when the mirror assembly is at the neutral state.

20. The switchable optical mirror device of claim 18, wherein the cantilever is substantially parallel to the substrate when the mirror assembly is at the deflected state.

21. The switchable optical mirror device of claim 17, further comprising a first electrode electrically coupled to the substrate, and a second electrode electrically coupled to the mirror assembly.

22. The switchable optical mirror device of claim 17, further comprising a highly reflective coating layer on the reflector.

23. The switchable optical mirror device of claim 17, further comprising an insulating layer disposed between the substrate and the mirror assembly.

24. A method for operating an optical mirror switch, comprising:
applying a voltage between a cantilever and a substrate in an optical mirror device comprising:
a substrate defining a gap space;
a mirror assembly disposed on the substrate and deflectable in the gap space, the mirror assembly comprising a free end cantilever and a reflector on the cantilever, wherein an end of the cantilever is anchored on the substrate adjacent a side of the gap space through an elastic member; and
the voltage being configured to drive the cantilever to vibrate at a mechanical resonant frequency.

25. The method of claim 24, wherein the mechanical resonant frequency ranges from about 1 kHz to about 100 kHz.

26. The method of claim 24 wherein the optical mirror device further comprises a stop component, the stop component configured to confine displacement of the cantilever to a space between the stop component and a surface on which the gap space is formed.

27. The method of claim 26 wherein the optical mirror device is configured to withstand mechanical vibration from 10 to 2000 Hz and impact of to 2000 G.
